(19) United States
(12) Patent Application Publication
(10) Pub. No.: US 2005/0201763 A1
(43) Pub. Date: Sep. 15, 2005

(54) Optical element wafer and method for manufacturing the same, burn-in apparatus for optical element wafer, and burn-in method for optical element wafer

(75) Inventor: Tsuyoshi Kaneko, Shimosuwa-machi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/050,681

(22) Filed: Feb. 7, 2005

(30) Foreign Application Priority Data
Mar. 10, 2004 (JP) 2004-067568

(51) Int. Cl. H01L 27/15; H01L 29/26

(52) U.S. Cl. 398/212; 257/79

(57) ABSTRACT

To provide an optical element wafer that can lower the cost of a burn-in step for the optical element wafer. An optical element wafer in accordance with the present invention includes a substrate, a plurality of optical elements formed above the substrate, and a burn-in electrode formed above the substrate, in an area different from an element forming area where the optical elements are formed, wherein the optical element includes a first semiconductor layer formed above the substrate, an active layer formed above the first semiconductor layer, a second semiconductor layer formed above the active layer, a first electrode that is electrically connected to the first semiconductor layer, and a second electrode that is electrically connected to the second semiconductor layer. Each of the optical elements shares the first semiconductor layer, and the burn-in electrode is electrically connected to the first semiconductor layer.

### BACKGROUND

The present invention relates to optical element wafers, methods for manufacturing the same, burn-in apparatuses for optical element wafers, and burn-in methods for optical element wafers.

Optical elements, which are represented by semiconductor lasers, may change their characteristics when an electrical current is circulated after they have been completed. To resolve such an initial change, a current may be circulated in a semiconductor laser before shipping in a high temperature state for a predetermined period of time to stabilize its characteristics, i.e., a so-called burn-in step may be conducted.

Also, surface-emitting type optical elements, which are represented by light emitting diodes and surface-emitting type semiconductor lasers, can be evaluated for their characteristics in the state of a wafer, and a burn-in step can be conducted in the wafer level.

### SUMMARY

It is an object of the present invention to provide optical element wafers and methods for manufacturing the same, which can lower the cost of the step of burning in optical element wafers.

Also, it is an object of the present invention to provide apparatuses for burning in optical element wafers and methods for burning in optical element wafers, to which optical element wafers of the present invention are applied.

An optical element wafer in accordance with the present invention comprises: a substrate; a plurality of optical elements formed above the substrate; and a burn-in electrode formed above the substrate, in an area different from an element forming area where the optical elements are formed, wherein the optical element includes a first semiconductor layer formed above the substrate, an active layer formed above the first semiconductor layer, a second semiconductor layer formed above the active layer, a first electrode that is electrically connected to the first semiconductor layer, and a second electrode that is electrically connected to the second semiconductor layer, wherein each of the optical elements shares the first semiconductor layer, and the burn-in electrode is electrically connected to the first semiconductor layer.

In an optical element wafer in accordance with the present invention, the case where another specific element (hereafter referred to as “B”) is formed above a specific element (hereafter referred to as “A”), includes a case where B is formed directly on A, and a case where B is formed through another element above A.

According to this optical element wafer, the burn-in electrode is formed in an area that is different from the element forming area. Also, each of the optical elements has the first semiconductor layer that is commonly shared. Also, the burn-in electrode is electrically connected to the first semiconductor layer. Accordingly, when the optical element wafer is burnt in, the first semiconductor layer is set at a common potential, and each of the optical elements can be driven by using the burn-in electrode and the second electrode. In other words, when the burn-in step is conducted, the first electrode and the second electrode do not need to be used together for driving the optical element.

Accordingly, with a burn-in apparatus that is used in the step of burning in the optical element wafer described above, the burn-in step can be conducted by providing one probe for each of the optical elements for the second electrode. In other words, the probe does not need to be provided for each of the optical elements for the first electrode. As a consequence, in accordance with the present optical element wafer, the number of probes provided on a probe card can be reduced in half, compared to the case where the probes are provided for the respective corresponding optical elements for the first electrode and for the second electrode. The price of the probe card is mainly determined by the number of the probes. According to the optical element wafer, the number of the probes can be reduced in half, and therefore the cost for the optical element wafer burn-in step can be considerably reduced.

In the optical element wafer in accordance with the present invention, the optical element can function as a surface-emitting type semiconductor laser, the first semiconductor layer can be a first mirror, and the second semiconductor layer can be a second mirror.

In the optical element wafer in accordance with the present invention, the optical element can function as a light emitting diode, the first semiconductor layer can have a first conductivity type, and the second semiconductor layer can have a second conductivity type.

An optical element wafer in accordance with the present invention comprises: a substrate; a plurality of optical elements formed above the substrate; and a burn-in electrode formed above the substrate, in an area different from an element forming area where the optical elements are formed, wherein the optical element includes a first semiconductor layer formed above the substrate, a light absorbing layer formed above the first semiconductor layer, a second semiconductor layer formed above the light absorbing layer, a first electrode that is electrically connected to the first semiconductor layer, and a second electrode that is electrically connected to the second semiconductor layer, wherein each of the optical elements shares the first semiconductor layer, and the burn-in electrode is electrically connected to the first semiconductor layer.

In the optical element wafer in accordance with the present invention, the optical element can function as a photodiode, the first semiconductor layer can have a first conductivity type, and the second semiconductor layer can have a second conductivity type.

In the optical element wafer in accordance with the present invention, the burn-in electrode may be formed above the first semiconductor layer, and at an outer circumference of the first semiconductor layer.

In accordance with the optical element wafer, the burn-in electrode that continuously surrounds the element forming area can be formed. Consequently, a driving current (a current for driving the optical element) having a uniform distribution can be circulated, compared to the case where the burn-in electrode is partially formed. Also, because the burn-in electrode is formed in an outer circumference of the wafer, the element forming area can be made broader.

In the optical element wafer in accordance with the present invention, the burn-in electrode may be formed above the first semiconductor layer, in a shape that divides the element forming area.

In accordance with the optical element wafer, the area of the burn-in electrode as viewed in a plan view can be made greater. Consequently, a greater current can be circulated. Also, because the element forming area that is surrounded by the burn-in electrode is made smaller, such that a driving current with an even more uniform distribution can be circulated.

In the optical element wafer in accordance with the present invention, the burn-in electrode can have a width that is 1 mm or greater but 5 mm or smaller.

A method for manufacturing an optical element in accordance with the present invention pertains to a method for manufacturing an optical element wafer including a plurality of optical elements having a first semiconductor layer, an active layer and a second semiconductor layer, and includes the steps of: laminating semiconductor layers for forming at least the first semiconductor layer, the active layer and the second semiconductor layer above a substrate; patterning the semiconductor layers to form the second semiconductor layer; patterning the semiconductor layers to form the active layer; patterning the semiconductor layers to form the first semiconductor layer; forming a first electrode and a burn-in electrode to be electrically connected to the first semiconductor layer; and forming a second electrode to be electrically connected to the second semiconductor layer, wherein the burn-in electrode is formed in an area different from an element forming area where the optical elements are formed.

In accordance with the manufacturing method for an optical element wafer, the burn-in electrode and the first electrode of the optical element can be formed by the same process. In other words, an exclusive step for forming the burn-in electrode is not needed, such that the method for manufacturing an optical element can be simplified.

In the method for manufacturing an optical element wafer in accordance with the present invention, the optical element may be formed to function as a surface-emitting type semiconductor laser, the first semiconductor layer may be formed to become a first mirror, and the second semiconductor layer may be formed to become a second mirror.

In the optical element wafer in accordance with the present invention, the optical element may be formed to function as a light emitting diode, the first semiconductor layer may be formed to have a first conductivity type, and the second semiconductor layer may be formed to have a second conductivity type.

A method for manufacturing an optical element wafer in accordance with the present invention pertains to a method for manufacturing an optical element wafer including a plurality of optical elements having a first semiconductor layer, a light absorbing layer and a second semiconductor layer, and includes the steps of: laminating semiconductor layers for forming at least the first semiconductor layer, the light absorbing layer and the second semiconductor layer above a substrate; patterning the semiconductor layers to form the second semiconductor layer; patterning the semiconductor layers to form the light absorbing layer; patterning the semiconductor layers to form the first semiconductor layer; forming a first electrode and a burn-in electrode to be electrically connected to the first semiconductor layer; and forming a second electrode to be electrically connected to the second semiconductor layer, wherein each of the optical elements shares the first semiconductor layer, and the burn-in electrode is formed in an area different from an element forming area where the optical elements are formed.

In the optical element wafer in accordance with the present invention, the optical element may be formed to function as a photodiode, the first semiconductor layer may be formed to have a first conductivity type, and the second semiconductor layer may be formed to have a second conductivity type.

A burn-in apparatus for an optical element wafer in accordance with the present invention may include: a stage on which the optical element wafer described above is mounted; a fixing member for fixing the optical element wafer to the stage; a probe that is brought in contact with the second electrode of the optical element; a power supply circuit section that is capable of applying at least one of a current and a voltage to a path extending from the probe, through the optical element and burn-in electrode to the fixing member; and a position adjusting section that adjusts a position of the probe with respect to the second electrode of the optical element.

In the burn-in apparatus for an optical element wafer in accordance with the present invention may include a temperature adjusting section that adjusts a temperature environment where the optical element wafer is burnt in.

A burn-in method for burning in an optical element wafer in accordance with the present invention pertains to the burn-in method for burning in an optical element wafer, and may include the steps of: contacting a probe to the second electrode of the optical element; and applying at least one of a current and a voltage to a path extending from the probe, through the second electrode, the second semiconductor layer, the active layer and the first semiconductor layer, to the burn-in electrode.

In the burn-in method for burning in an optical element wafer in accordance with the present invention, a plurality of probes may be simultaneously brought in contact with the second electrodes of the plurality of optical elements, and at least one of a current and a voltage may be applied to each of the optical elements.

The burn-in method for burning in an optical element wafer in accordance with the present invention may be conducted in a temperature environment at 30° C. or higher.

### BRIEF DESCRIPTION OF THE DRAWINGS

FIG. 1 is a cross-sectional view schematically showing an optical element wafer in accordance with an embodiment;

FIG. 2 is a plan view schematically showing an optical element wafer in accordance with an embodiment;

FIG. 3 is a plan view schematically showing an optical element wafer in accordance with an embodiment;

FIG. 4 is a plan view schematically showing an optical element wafer in accordance with an embodiment;

FIG. 5 is a plan view schematically showing an optical element wafer in accordance with an embodiment;

FIG. 6 is a plan view schematically showing an optical element wafer in accordance with an embodiment;

FIG. 7 is a cross-sectional view schematically showing a method for manufacturing an optical element wafer in accordance with an embodiment;

FIG. 8 is a cross-sectional view schematically showing a method for manufacturing an optical element wafer in accordance with an embodiment;

FIG. 9 is a cross-sectional view schematically showing a method for manufacturing an optical element wafer in accordance with an embodiment;

FIG. 10 is a cross-sectional view schematically showing an optical element wafer in accordance with an embodiment;

FIG. 11 is a cross-sectional view schematically showing an optical element wafer in accordance with an embodiment;

FIG. 12 is an exterior perspective view schematically showing an example of a burn-in apparatus for an optical element wafer in accordance with an embodiment;

FIG. 13 is a cross-sectional view schematically showing a main portion of a burn-in apparatus 300 in accordance with an embodiment; and

FIG. 14 is a functional block diagram of the burn-in apparatus 300 in accordance with the embodiment.

### DETAILED DESCRIPTION OF EMBODIMENTS

Preferred embodiments of the present invention are described below with reference to the accompanying drawings.

1. Structure of Optical Element Wafer

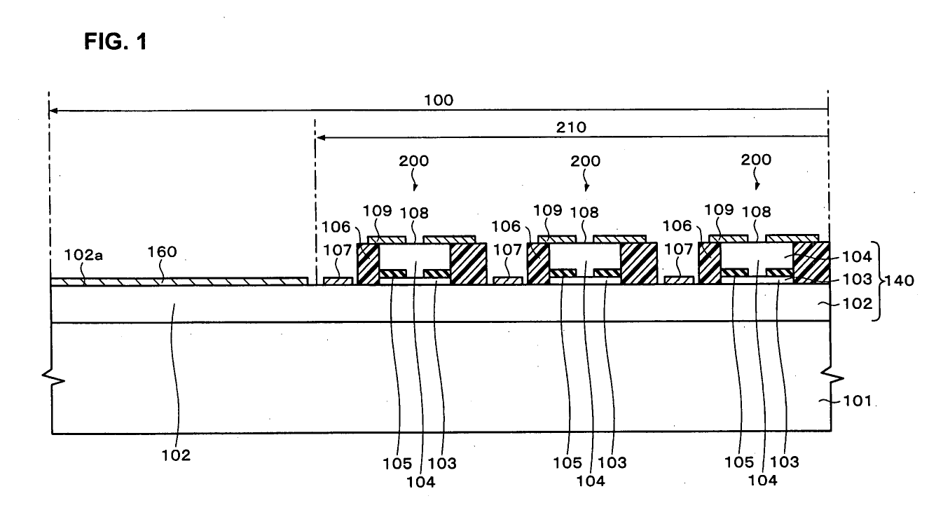

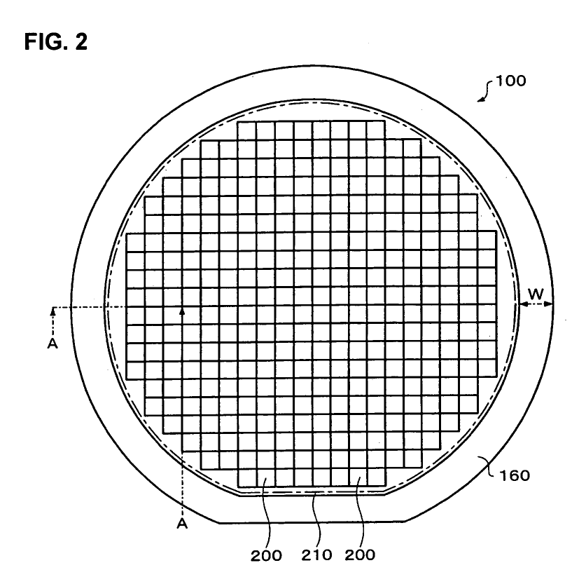

FIG. 1 is a cross-sectional view schematically showing an optical element wafer 100 in accordance with an embodiment of the present invention. Also, FIG. 2 is a plan view schematically showing the optical element wafer 100 shown in FIG. 1. It is noted that FIG. 1 is a view showing a cross section taken along a line A-A in FIG. 2. Also, the illustration of optical elements 200 in FIG. 2 is simplified.

An optical element wafer 100 in accordance with an embodiment of the present invention includes, as shown in FIG. 1 and FIG. 2, a substrate (a GaAs substrate in accordance with the present embodiment) 101, a plurality of optical elements 200, and a burn-in electrode 160. In the present embodiment, the case where the optical element 200 has a function as a surface-emitting type semiconductor laser is shown.

Next, constituting elements of the optical element wafer 100 are described.

The optical element 200 includes a vertical resonator (hereafter referred to as a “resonator”) 140 formed over a substrate 101, a first electrode 107, a second electrode 109, and an insulation layer 106. The optical element 200 is formed above the substrate 101, in an element forming area 210 of the optical element wafer 100.

The resonator 140 includes a first semiconductor layer 102, an active layer 103 and a second semiconductor layer 104. The resonator 140 is formed from, for example, the first semiconductor layer that is a distributed reflection type multilayer mirror of 40 pairs of alternately laminated n-type Al_{0.9}Ga_{0.1}As layers and n-type Al_{0.15} Ga_{0.85}As layers (hereafter called a “first mirror”) 102, the active layer 103 composed of GaAs well layers and Al_{0.3}Ga_{0.7}As barrier layers in which the well layers include a quantum well structure composed of three layers, and the second semiconductor layer that is a distributed reflection type multilayer mirror of 25 pairs of alternately laminated p-type Al_{0.9}Ga_{0.1}As layers and p-type Al_{0.15} Ga_{0.85}As layers (hereafter called a “second mirror”) 104, which are successively stacked in layers. It is noted that the composition of each of the layers and the number of the layers forming the first mirror 102, the active layer 103 and the second mirror 104 are not particularly limited to the above.

As shown in FIG. 1, each of the optical elements 200 shares the first mirror 102. In other words, the first mirror 102 is not separated by the optical elements 200. That is, the first mirror 102 is formed on the entire surface of the substrate 101.

The second mirror 104 is formed to be p-type by, for example, doping C, Zn, Mg or the like, and the first mirror 102 is formed to be n-type by, for example, doping Si, Se or the like. Accordingly, a pin diode is formed by the second mirror 104, the active layer 103 in which no impurity is doped, and the first mirror 102.

The second mirror 104 and the active layer 103 compose a columnar semiconductor deposition body (hereafter referred to as a “columnar section”) 130. As shown in FIG. 1, the columnar section has a side surface that is covered by the insulation layer 106.

Furthermore, an insulation layer 105 that functions as a current constricting layer is formed in a region near the active layer 103 among layers composing the columnar section. The current constricting layer 105 can have a ring shape along a circumference of the columnar section. Also, the insulation layer 105 for current constriction may be composed of, for example, aluminum oxide.

The second electrode 109 is formed on the second mirror 104 and the insulation layer 106. The upper surface of the second mirror 104 in an opening section of the second electrode 109 defines an emission surface 108 of laser light. The second electrode 109 consists of, for example, a multilayer film of an alloy of gold (Au) and zinc (Zn), and gold (Au).

Further, a first electrode 107 is formed on the first mirror 102. The first electrode 107 consists of a multilayer film of an alloy of gold (Au) and germanium (Ge), and Au, for example. In other words, in the optical element 200 shown in FIG. 1, the second electrode 109 connects to the second mirror 104, and the first electrode 107 connects to the first mirror 102. A current is injected into the active layer 103 by the second electrode 109 and the first electrode 107.

The materials to form the first electrode 107 and the second electrode 109 are not limited to those described above, and, for instance, metals such as chrome (Cr), titanium (Ti), nickel (Ni), platinum (Pt) or these alloys can be used depending on the requirements for adhesion enforcement, diffusion prevention, anti-oxidation, and the like.

The burn-in electrode 160 is electrically connected to the first mirror 102. Concretely, as shown in FIG. 1 and FIG. 2, the burn-in electrode 160 is formed on the first mirror 102 and in an area different from the element forming area 210 where the optical elements 200 are formed. More specifically, the burn-in electrode 160 is formed on an upper surface 102a of the first mirror 102, and along a periphery of the first mirror 102. For example, the width W of the burn-in electrode shown in FIG. 2 can be 1 mm or greater but 5 mm or smaller. When the width W of the burn-in electrode is 1 mm or greater, a desired current can be circulated in the optical element 200 without a problem. Moreover, the contact area of a fixing member 308 to be described below and the burn-in electrode 160 can be enlarged. The element forming area 210 can be secured to its maximum when the width W of the burn-in electrode is 5 mm or less. In general, in an optical element wafer, good characteristics of an optical element might not be obtained in an area of about 5 mm width along its outer peripheral edge in the upper surface of the optical element wafer, and therefore, optical elements may not be formed in this area. By forming the burn-in electrode 160 in the area where no optical element is formed, the number of optical elements 200 to be taken does not have to be reduced. For example, the same material as that of the first electrode 107 described above can be used as the material for the burn-in electrode.

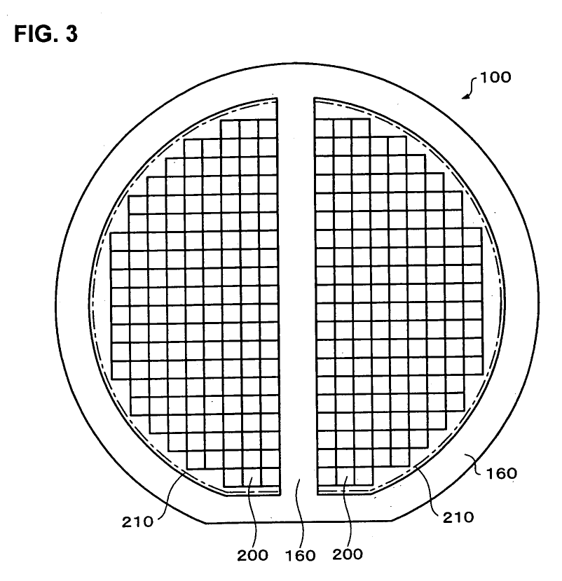

In the optical element wafer 100 shown in FIG. 1 and FIG. 2, the case in which the burn-in electrode 160 is formed on the upper surface 102a of the first mirror 102 along a periphery of the first mirror 102 is indicated. However, as shown in FIG. 3-FIG. 6, the burn-in electrode 160 can be formed in a shape that divides the element forming area 210 of the optical element wafer 100. FIG. 3-FIG. 6 are plan views schematically showing optical element wafers 100 in such cases. More specifically, they may be formed as follows.

In the optical element wafer 100 shown in FIG. 3, the burn-in electrode 160 is formed on an upper surface 102a (see FIG. 1) of the first mirror 102, along a periphery of the first mirror 102. Furthermore, the burn-in electrode 160 is formed in a linear shape that divides the element forming area 210. In other words, the element forming area 210 is divided by the burn-in electrode 160 having a linear plane configuration in the center of the first mirror 102 (optical element wafer 100).

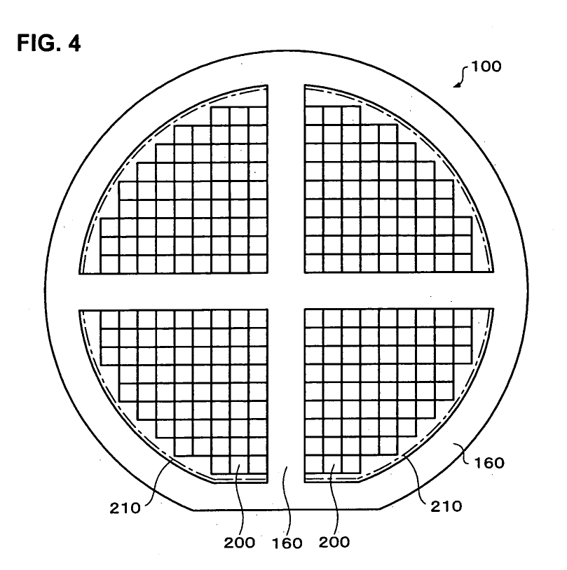

In the optical element wafer 100 shown in FIG. 4, the burn-in electrode 160 is formed on an upper surface 102a (see FIG. 1) of the first mirror 102, along a periphery of the first mirror 102. Furthermore, the burn-in electrode 160 is formed in a cross shape that divides the element forming area 210. In other words, the element forming area 210 is divided by the burn-in electrode 160 having a cross plane configuration.

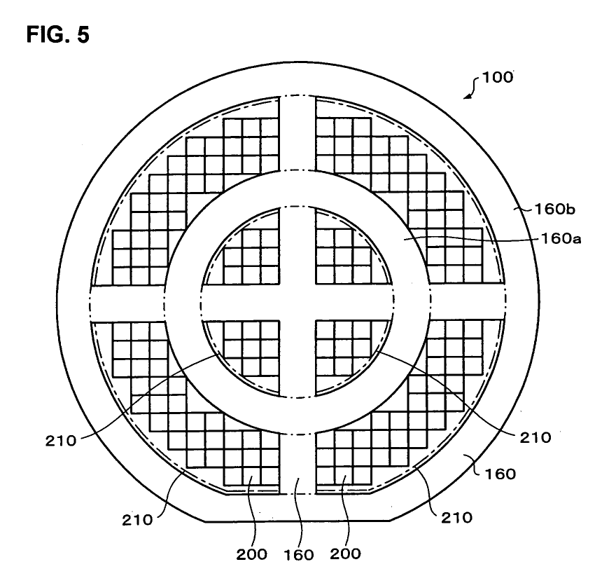

In the optical element wafer 100 shown in FIG. 5, the burn-in electrode 160 is formed on an upper surface 102a (see FIG. 1) of the first mirror 102, along a periphery of the first mirror 102. Furthermore, the burn-in electrode 160 is formed in a cross shape that divides the element forming area 210. Moreover, the burn-in electrode 160 is formed in a circular ring shape with its center at an intersection of the cross, which divides the element forming area 210. A portion 160a in the circular ring shape is formed on the inner side of a portion 160b that is formed at the periphery of the first mirror 102. In other words, the element forming area 210 is divided by the burn-in electrode 160 having a cross plane configuration, and a circular ring-shaped plane configuration.

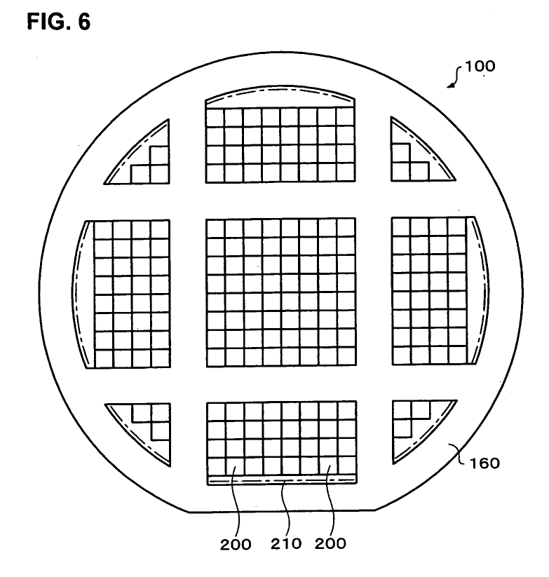

In the optical element wafer 100 shown in FIG. 6, the burn-in electrode 160 is formed on an upper surface 102a (see FIG. 1) of the first mirror 102, along a periphery of the first mirror 102. Furthermore, the burn-in electrode 160 is formed in a lattice-shaped configuration that divides the element forming area 210. In other words, the element forming area 210 is divided by the burn-in electrode 160 having a lattice-shaped plane configuration.

2. Optical Element Wafer Manufacturing Method

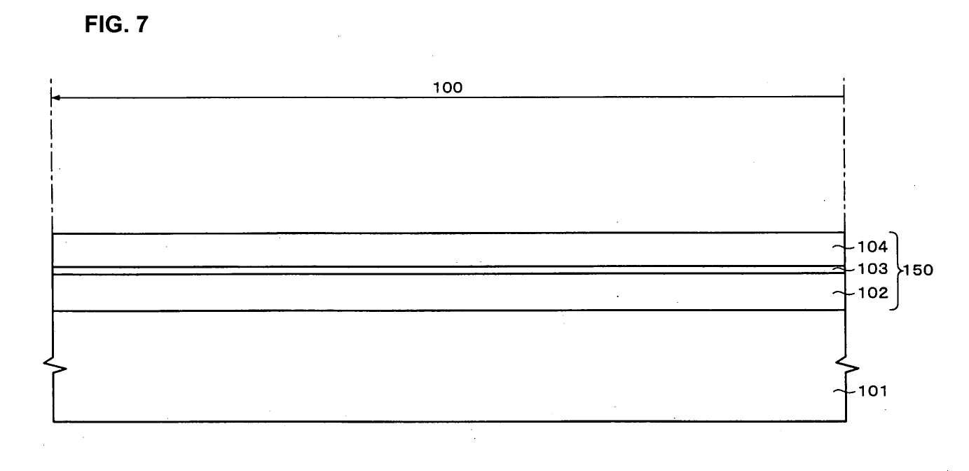

An example of a method of manufacturing the optical element wafer laser 100 in accordance with an embodiment of the present invention is described with reference to FIG. 1, FIG. 2 and FIG. 7-11. FIG. 7-FIG. 11 are cross-sectional views schematically showing the steps of the method of manufacturing the optical element wafer 100 according to the present embodiment, each of which corresponds to the cross section indicated in FIG. 1.

(1) First, on a surface of a semiconductor substrate 101 composed of n-type GaAs, a semiconductor multilayer film 150 shown in FIG. 7 is formed by epitaxial growth while modifying the composition. It is noted here that the semiconductor multilayer film 150 is formed from, for example, a first mirror 102 of 40 pairs of alternately laminated n-type Al_{0.9}Ga_{0.1}As layers and n-type Al_{0.15} Ga_{0.85}As layers, an active layer 103 composed of GaAs well layers and Al_{0.3}Ga_{0.7}As barrier layers in which the well layers include a quantum well structure composed of three layers, and a second mirror 104 of 25 pairs of alternately laminated p-type Al_{0.9}Ga_{0.1}As layers and p-type Al_{0.15} Ga_{0.85}As layers. These layers are successively stacked in layers on the semiconductor substrate 101 to thereby form the semiconductor multilayer film 150.

When growing the second mirror 104, at least one layer thereof adjacent to the active layer 103 can be formed as an AlAs layer or an AlGaAs layer that is later oxidized and becomes a first insulation layer 105 for current constriction. Al composition of the AlGaAs layer that is to become the insulation layer 105 is, for example, 0.95 or greater. Also, the uppermost surface layer of the second mirror 104 may preferably be formed with a high carrier density such that ohmic contact can be readily made with an electrode (second electrode 109).

The temperature at which the epitaxial growth is conducted is appropriately decided depending on the growth method, the kind of raw material, the type of the semiconductor substrate 101, and the kind, thickness and carrier density of the semiconductor multilayer film 150 to be formed, and in general may preferably be 450° C.-800° C. Also, the time required for conducting the epitaxial growth is appropriately decided like the temperature. Also, a metal-organic chemical vapor deposition (MOVPE: Metal-Organic Vapor Phase Epitaxy) method, a MBE method (Molecular Beam Epitaxy) method or a LPE (Liquid Phase Epitaxy) method can be used as a method for the epitaxial growth.

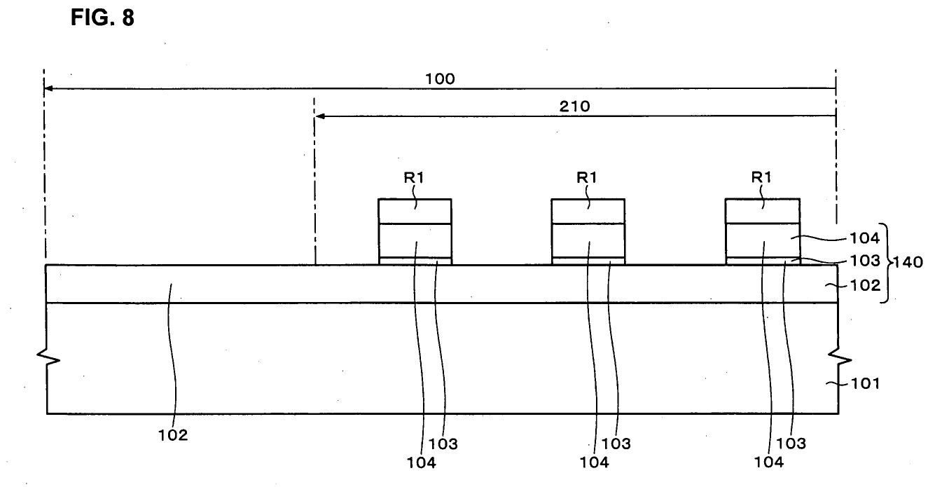

Then, resist is coated on the semiconductor multilayer film 150, and then the resist is patterned by a lithography method, thereby forming a resist layer R1 having a specified pattern. The resist layer R1 is formed above an area where a second mirror 104 (see FIG. 1) is planned to be formed. Next, by using the resist layer R1 as a mask, the second mirror 104 and the active layer 103 are etched by, for example, a dry etching method, thereby forming a pillar-shaped semiconductor deposited body (columnar section), as shown in FIG. 8. Then, the resist layer R1 is removed.

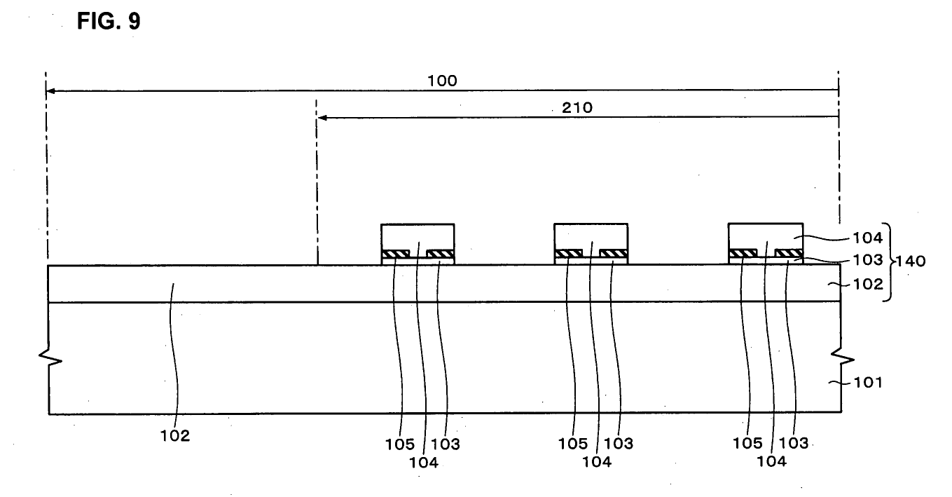

(3) Next, as indicated in FIG. 9, the substrate 101 on which the columnar section is formed through the aforementioned steps is placed in a water vapor atmosphere at about 400° C., for example. As a result, the layer having a high Al composition (layers with an Al composition, for example, being 0.95 or higher) provided in the second mirror 104 described above is oxidized from its side surface, thereby forming an insulation layer for current constriction 105. The oxidation rate depends on the temperature of the furnace, the amount of water vapor supply, and the Al composition and the film thickness of the layer to be oxidized.

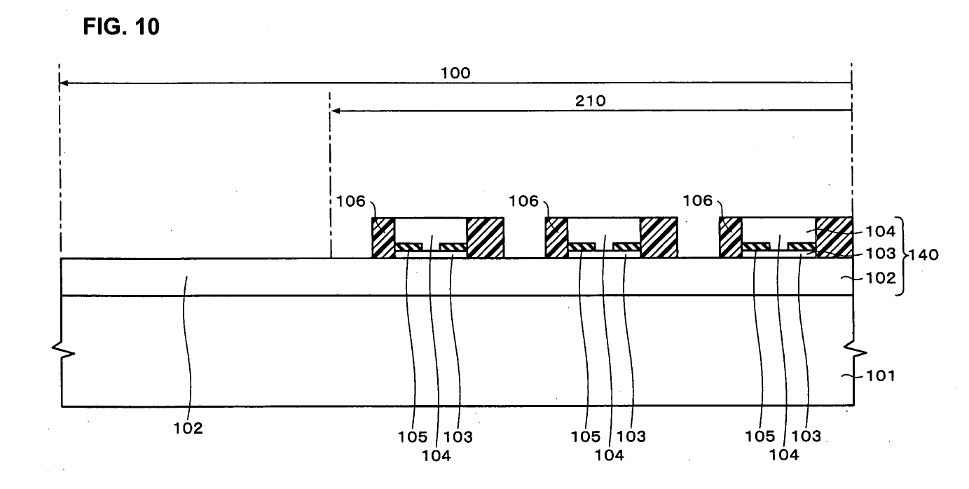

(4) Next, an insulation layer 106 is formed on the first mirror 102 around the columnar section (the second mirror 104, the current constricting layer 105 and the active layer 103), as shown in FIG. 10.

For example, resin can be used for the insulation layer 106. As the resin, for example, polyimide resin, acrylic resin, epoxy resin or the like can be used. These materials can be readily made in thick films, and readily processed.

Here, the case where a precursor of polyimide resin is used as the material for forming the insulation layer 106 is described. First, for example, by using a spin coat method, the precursor (precursor of polyimide resin) is coated on the substrate 101, thereby forming a precursor layer. It is noted that, as the method for forming the precursor layer, besides the spin coat method described above, another known technique, such as, a dipping method, a spray coat method, a droplet discharge method or the like can be used.

Then, the substrate 101 is heated by using, for example, a hot plate or the like, thereby removing the solvent, and then is placed in a furnace at about 350° C. to thereby imidize the precursor layer, thereby forming a polyimide resin layer that is almost completely set. Then, as shown in FIG. 10, the polyimide resin layer is patterned by using a known lithography technique, thereby forming the insulation layer 106. As the etching method used for patterning, a dry etching method or the like can be used. Dry etching can be conducted with, for example, oxygen or argon plasma.

In the method for forming the insulation layer 106 described above, an example in which a precursor layer of polyimide resin is set, and then patterning is conducted is presented. However, patterning may be conducted before the precursor layer of polyimide resin is set. As the etching method used for this patterning, a wet etching method or the like can be used. The wet etching can be conducted with, for example, an alkaline solution or an organic solution.

In the above-described example, a resin is used for the insulation layer 106. However, inorganic dielectric materials or their laminated films can also be used. For example, as the inorganic dielectric material, silicon nitride, silicon oxide, aluminum nitride, silicon carbide, diamond or the like can be used. These materials in a thin film form have good insulation property, and good thermal conductivity, and can be readily processed. In this case, specifically, a method for forming the insulation layer 106 may be conducted as follows.

First, an insulation layer (not shown) is formed over the entire surface of the substrate 101 on which the columnar section is formed. This insulation layer can be formed by, for example, plasma CVD. Next, by using a known lithography technique, the insulation layer is patterned, thereby forming an insulation layer 106. As the etching method used for this patterning, a dry etching method or a wet etching method can be used. The dry etching can be conducted with plasma including fluorine radical, for example. The wet etching can be conducted with hydrofluoric acid, for example.

(5) Next, the steps of forming a first electrode 107 and a second electrode 109 for injecting a current in the active layer 103, an emission surface of laser light 108, and a burn-in electrode 160 (see FIG. 1) are described.

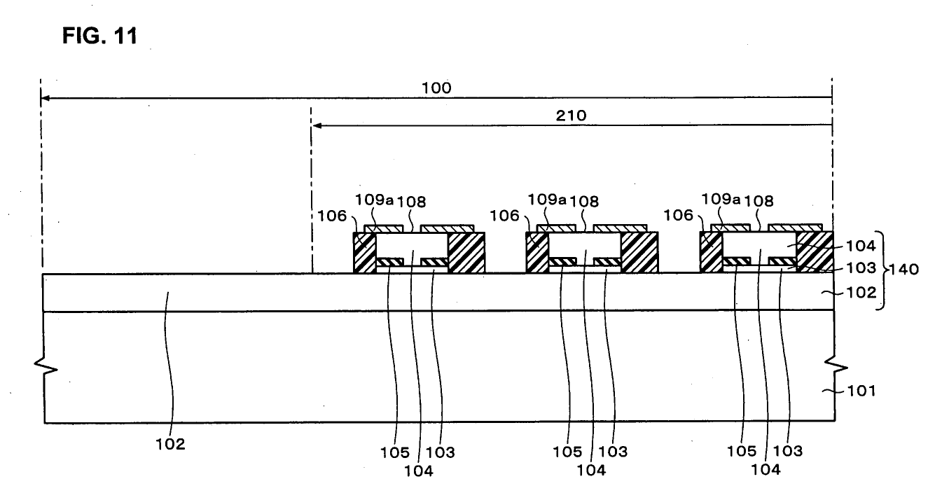

First, before the first electrode 107 and the second electrode 109 are formed, the upper surface of the second mirror 104 and the first mirror 102 are washed by using a plasma processing method or the like, if necessary. As a result, an element with more stable characteristics can be formed. Next, a laminated film of an alloy of gold (Au) and zinc (Zn), and gold (Au), for example, are formed over the entire surface by, for example, a vacuum deposition method or a sputter method. Then, a portion where a laminated film 109a is not formed is formed on the upper surface of the second mirror 104 by a lift-of method, as shown in FIG. 11.

A portion of the upper surface of the second mirror 104 where the laminated film 109a is not formed becomes to be the emission surface 108. It is noted that, in this step, a dry etching method or a wet etching method can be used instead of the lift-off method.

Next, by using a similar method, for example, by patterning a laminated film of an alloy of gold (Au) and germanium (Ge), and gold (Au), for example, a first electrode 107 and a burn-in electrode 160 are formed on the first mirror 102 (see FIG. 1). Next, an annealing treatment is conducted. The temperature of the annealing treatment depends on the electrode material. This is usually conducted at about 400° C. for the electrode material used in the present embodiment. By the steps described above, the first electrode 107, the second electrode 109 and the burn-in electrode 160 (see FIG. 1) are formed. It is noted that, in the step described above, the first electrode 107 and the burn-in electrode 160 are patterned at the same time, but the first electrode 107 and the burn-in electrode 160 can be formed independently from each other.

By the process described above, the optical element wafer 100 shown in FIG. 1 and FIG. 2 is obtained.

3. Burn-In Apparatus for Optical Element Wafer and its Controlling Method

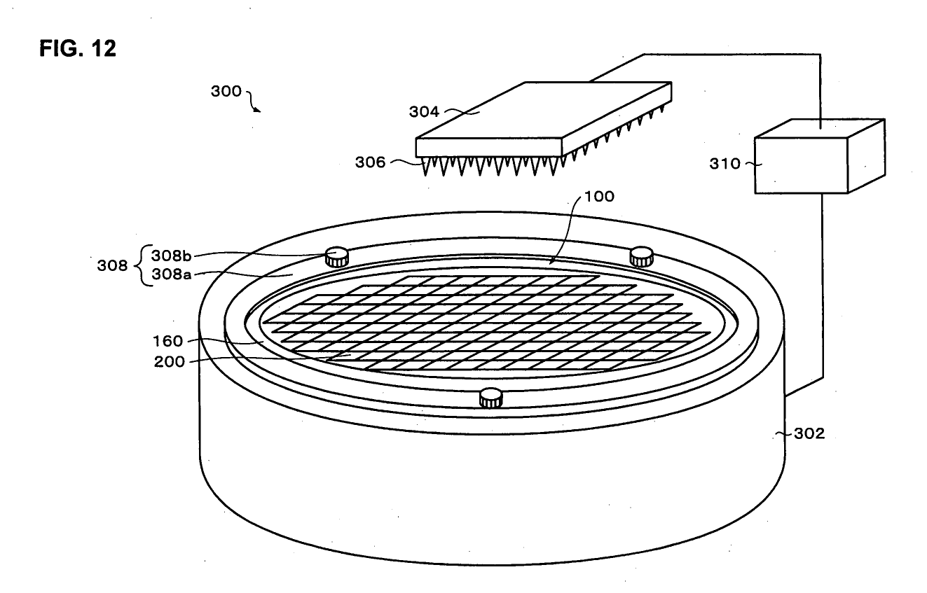

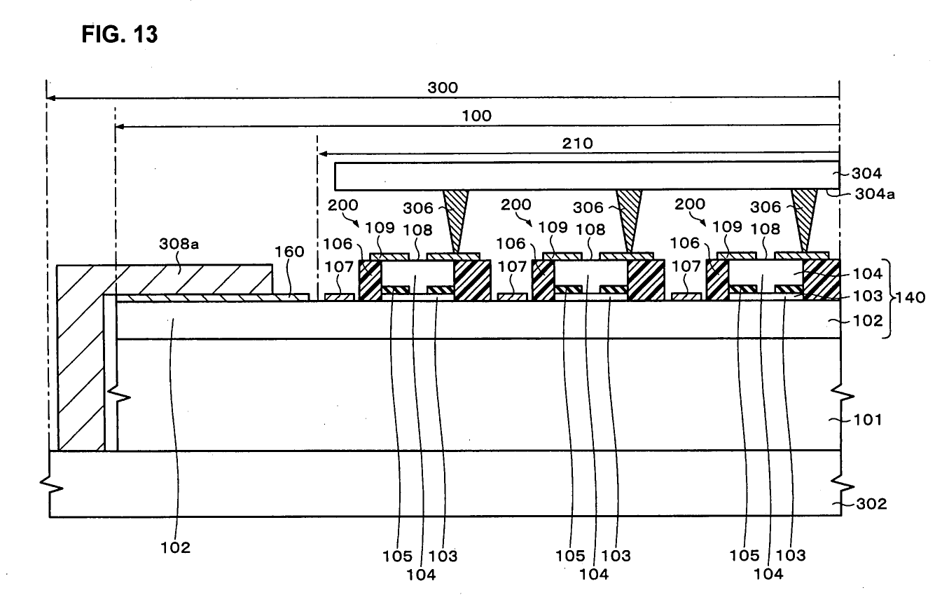

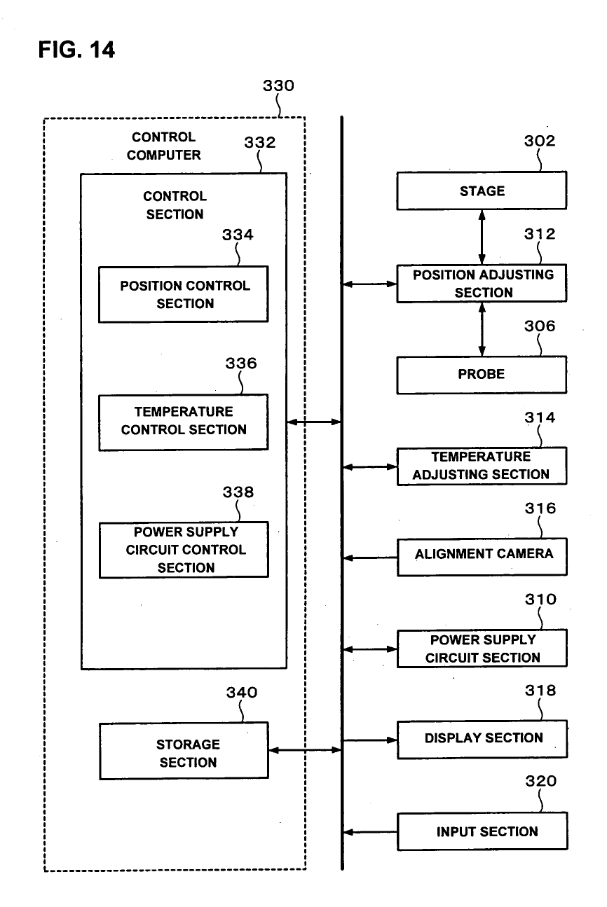

FIG. 12 is an external perspective view schematically showing one example of a burn-in apparatus 300 for burning in the optical element wafer 100, which is suitable for burning in the optical element wafer 100 in accordance with an embodiment of the present invention. FIG. 13 is a cross-sectional view schematically showing a main portion of the burn-in apparatus 300 in accordance with the present embodiment. FIG. 14 shows an example of a functional block diagram of the burn-in apparatus 300 in accordance with the present embodiment. It is noted that the burn-in apparatus in accordance with the present embodiment does not necessarily include all of the constituting elements (the respective sections) shown in FIG. 12-FIG. 14, and may have a structure in which a part thereof is omitted.

The burn-in apparatus 300 in accordance with the present embodiment has a probe function for an optical element wafer 100 in which a plurality of optical elements 200 are formed. The burn-in apparatus 300 in accordance with the present embodiment includes a stage 302, a probe card 304, a probe 306, a fixing member 308, a power supply circuit section 310, a position adjusting section 312, a temperature adjusting section 314, and a control computer 330.

Each of the sections composing the burn-in apparatus 300 in accordance with the present embodiment is described below.

On the stage 302, an optical element wafer 100 in which a plurality of optical elements 200 are formed is mounted. A plurality of probes 306 are provided on a lower surface 304a of the probe card 304, as shown in FIG. 12 and FIG. 13. The probes 306 can be brought in contact with second electrodes 109 of the corresponding optical elements 200, respectively, as shown in FIG. 13.

The fixing member 308 can fix the optical element wafer 100 to the stage 302. For example, as shown in FIG. 12, the fixing member 308 includes a ring member 308a having a ring-shaped plane configuration, and screws 308b. The ring member 308a covers the periphery of the optical element wafer 100. More specifically, as shown in FIG. 13, the ring member 308a covers at least a part of the burn-in electrode 160 that is formed on the first mirror 102, and at the periphery of the first mirror 102. In other words, the ring member 308a contacts the burn-in electrode 160. Further, the ring member 308a is affixed to the stage 302 by the screws 208b. It is noted that, in the illustrated example described above, the fixing member 308 is formed from the ring member 308a and the screws 308b. However, the fixing member 308 is not particularly limited to be above, and can be anything that can fix the optical element wafer 100 to the stage 302.

A material for the fixing member 308 may be one that allows the fixing member 308 to electrically connect to the burn-in electrode 160. As the material for the fixing member 308, a conductive material, such as, for example, a metal can be used.

The power source circuit section 310 can circulates a current in a path that extends from the probe 306, through the optical element 200, the burn-in electrode 160, and the fixing member 308 to the stage 302. The power source circuit section 310 can be formed from, for example, a DC power supply, and an electrical wiring having a desired circuit composition. It is noted that, in the illustrated example, a current is circuited in the stage 302. However, it can be designed such that a current may not be circulated in the stage 302. In this case, for example, the fixing member 308 may be directly connected to the power supply circuit section 310.

Although not illustrated in FIG. 12 or FIG. 13, the burn-in apparatus 300 in accordance with the present embodiment can include the position adjusting section 312. The position adjusting section 312 can adjust the position of the probe 306 with respect to the second electrode 109 of the optical element 200. The position adjusting section 312 has a structure that can move the stage 302 or the probe card 304, or both of the stage 302 and the probe card 304. For example, a known structure that uses rails and moves them on the rails can be enumerated as such a structure. The moving directions may be, for example, a vertical direction, a horizontal direction and a rotational direction.

Although not illustrated in FIG. 12 or FIG. 13, the burn-in apparatus 300 in accordance with the present embodiment can include a temperature adjusting section 314. The temperature adjusting section 314 can be used for adjusting the temperature environment where the optical element wafer 100 is burnt in. The temperature adjusting section 314 can use, for example, a Peltier device, an infrared ray heater, a thermostatic oven, or a combination of them.

Although not illustrated in FIG. 12 or FIG. 13, the burn-in apparatus 300 in accordance with the present embodiment can include an alignment camera 316. The alignment camera 316 obtains information for positioning by the position adjusting section 213, and can be used to adjust the relation between the position of the second electrode 109 of the optical element 200 on the stage 302 and the position of the probe 306 through operating in association with the control computer 330.

A display section 318 outputs images indicating set states, operation states (control states) or the like of the burn-in apparatus 300, and its functions can be realized by hardware such as a CRT, LCD, a touch panel type display or the like.

An input section 320 is provided such that the operator of the burn-in apparatus 300 inputs a variety of setting data and operation data, and its functions can be realized by hardware such as a keyboard, operation buttons, a touch panel type display, operation levers or the like.

A storage section 340 stores a variety of setting data (for example, position control data, power supply circuit control data, temperature control data, etc.), and becomes a work area to achieve various processing functions by the control section 332, and its functions can be achieved by hardware such as a RAM, ROM, optical disk (CD, DVD), magnet-optical disk (MO), magnetic disk, magnetic tape or the like. The control unit 332 performs various processings to operate the burn-in apparatus 300 in accordance with the present embodiment based on programs (data) stored in the storage section 340. In other words, the storage section 340 also stores control programs to make each section of the burn-in apparatus 300 of the present embodiment to function (programs to make the control computer 330 to execute the processings of each section).

A control section 332 (processor) performs various control processings based on input data from the input section 320 and the control programs stored in the storage section 340. Moreover, the control section 332 performs various processings, using the storage section 340 as a work area. Functions of the control section 332 can be realized by hardware such as a variety of processors (CPU, DSP, etc.), ASIC (gate array, etc.) or the like, or a program (control program). It is noted that the control computer 330 has a structure that includes the control section 332 and the storage section 340.

The control section 332 includes a position control section 334, a temperature control section 336, and a power supply circuit control section 338.

The position control section 334 controls the position adjusting section 312. More specifically, the position control section 334 calculates a contact position of the probe 306 with respect to the second electrode 109 of each of the optical elements 200 on the optical element wafer 100, according to a combination of the position of the stage 302 and the position of the probe card 304, and performs a control processing to move the stage 302 or the probe card 304, or both of the stage 302 and the probe card 304 to a specified position based on the calculation result.

The temperature control section 336 performs a processing to control to adjust the temperature environment where the burn-in step by the temperature adjusting section 314 is performed.

The power supply circuit control section 338 performs a processing to control driving of the optical element 200 by the power supply circuit section 310 (a processing to control the drive current to the optical element 200).

4. Burn-In Method for Optical Element

Next, an example of a burn-in method for an optical element wafer 100 in accordance with an embodiment of the present invention is described with reference to FIG. 12-FIG. 14.

(1) First, as shown in FIG. 13, tips of the probes 206 are brought in contact with the second electrodes 109 of the optical elements 200. More specifically, the position adjusting section 312 (not shown in FIG. 12 or FIG. 13) is controlled by the position control section 334, thereby moving the stage 302 or the probe card 304, or both of the stage 304 and the probe card 304. Accordingly, the probes 306 can be brought in contact with the second electrodes 109 of the optical elements 200.

(2) Next, a desired level of current for driving the optical elements 200 is continuously circulated for a desired length of time, under a desired temperature condition. More specifically, a current can be circulated in a path extending from the probe 306, through the second electrode 109, the second mirror 104, the active layer 103 and the first mirror 102, to the burn-in electrode 160. The amount of current may be, for example, about 30 mA for each of the optical elements 200. The temperature environment can be, for example, at 30° C. or higher. The energizing time may be, for example, about 1 day-2 days. When the temperature environment is at 30° C. or higher, the element temperature of the optical element 200 at the time of burn-in can be made higher than the quality assurance temperature of the optical element 200. The quality assurance temperature is, for example, about 80° C.-100° C. The amount of current, the temperature environment, the energizing time and the quality assurance temperature may be appropriately set, and is not particularly limited to the above-described condition.

By the process described above, the optical element wafer 100 can be burnt in.

It is noted that, after the burn-in of the optical element wafer 100 has been conducted, current-voltage characteristics of each optical element 200 can be measured by a known wafer prober, and can be confirmed if the characteristic values of the optical element 200 are within the standard values. In this instance, when the characteristics values of the optical element 200 are outside the standard values, the optical element 200 can be discarded.

5. Actions and Effect

In the optical element wafer 100 in accordance with the present embodiment, the burn-in electrode 160 is formed in an area different from the element forming area 210. Also, each of the optical elements 200 shares the first mirror 102. Moreover, the burn-in electrode 160 is electrically connected with the first mirror 102. Also, both of the first electrode 107 and the second electrode 109 are formed above the substrate 101, so as to enable surface bonding such as flip-chip bonding. Accordingly, when the optical element wafer 100 is burnt in, each of the optical elements 200 can be driven by setting the first mirror 102 at a common potential, and using the burn-in electrode 160 and the second electrode 109. In other words, the first electrode 107 is not required to be used to drive each of the optical elements 200 when the burn-in step is performed.

Consequently, the burn-in step can be performed through providing each one of the probes 306 of the burn-in apparatus 300 for the optical element wafer 100 (see FIG. 12-FIG. 14) for each of the optical elements 200 for the second electrode 109. In other words, the probe 306 does not need to be provided for each of the optical elements 200 for the first electrode 107. As a consequence, by the optical element wafer 100 in accordance with the present embodiment, the number of probes 306 provided on the probe card 304 can be reduced in half, compared to the case where the probes 306 are provided for the respective corresponding optical elements 200 for the first electrodes 107. The price of the probe card 304 is mainly determined by the number of the probes 306. With the optical element wafer 100 in accordance with the present embodiment, the number of the probes 306 can be reduced in half, and therefore the cost for the burn-in step for the optical element wafer 100 can be considerably reduced.

With the optical element wafer 100 in accordance with the present embodiment, when the optical element wafer 100 is burnt in, the first mirror 102 is set at a common potential, and the burn-in electrode 160 and the second electrode 109 are used to drive each of the optical elements 200. In other words, when the burn-in step is performed, the first electrode 107 does not need to be used for driving each of the optical elements 200.

Consequently, the burn-in step can be performed through providing each one of the probes 306 of the burn-in apparatus 300 for the optical element wafer 100 (see FIG. 12-FIG. 14) for each of the optical elements 200 for the second electrode 109. In other words, the probe 306 does not need to be provided for each of the optical elements 200 for the first electrode 107. As a consequence, by the optical element wafer 100 in accordance with the present embodiment, the pitch of the probes 306 provided on the probe card 304 can be doubled, compared to the case where the probes 306 are provided for the respective corresponding optical elements 200 for the first electrodes 107. Accordingly, the structure of the probe card 304 can be simplified.

With the optical element wafer 100 in accordance with the present embodiment, when the optical element wafer 100 is burnt in, as described above, the first mirror 102 can be set at a common potential, and the burn-in electrode 160 and the second electrode 109 are used to drive each of the optical elements 200. In other words, when the burn-in step is performed, the first electrode 107 does not need to be used for driving each of the optical elements 200.

Consequently, the burn-in step can be performed through bringing each one of the probes 306 of the burn-in apparatus 300 for the optical element wafer 100 (see FIG. 12-FIG. 14) in contact with the second electrode 109 of each of the optical elements 200. In other words, the probe 306 does not need to be brought in contact with both of the first electrode 107 and the second electrode 109 of each of the optical elements 200. With the optical element wafer 100 in accordance with the present embodiment, the burn-in step can be performed by bringing each of the probes 306 in contact only with the second electrode 109 of each of the optical elements, in contrast to the case where the probes 306 are brought in contact with both of the first electrode 107 and the second electrode 109 of each of the optical elements 200. Accordingly, the probe 306 needs to be positioned solely with respect to the second electrode 109 of the optical element 200. In other words, with the optical element wafer 100 in accordance with the present embodiment, the probe 306 can be readily positioned with respect to the optical element wafer 100.

In the optical element wafer 100 in accordance with the present embodiment, the burn-in electrode 160 that continuously surrounds the element forming area 210 can be formed. Accordingly, a drive current (a current for driving the optical element 200) having a uniform distribution can be circulated, compared to the case where the burn-in electrode 160 is partially formed. Also, due to the fact that the burn-in electrode 160 is formed at a periphery of the optical element wafer 100, a broader area can be taken up for the element forming area 210.

In the optical element wafer 100 in accordance with the present embodiment, when the optical element wafer 100 is burnt in, the second electrode 109 of the optical element 200 and the burn-in electrode 160 are used to drive the optical element 200. At this moment, the drive current circulates in the first mirror 102 commonly shared by each of the optical elements 200. In other words, even when an insulation material or a semi-insulation material is used for the substrate 101, the burn-in step can be performed without a problem. In other words, in the optical element wafer 100 in accordance with the present embodiment, an insulation material or a semi-insulation material is used for the substrate 101. For example, when the optical element 200 is operated as a single unit, there is a case where an insulation substrate or a semi-insulation substrate may be used to reduce a parasitic capacity and achieve a high-speed driving. In such a case, by using the optical element wafer 100 in accordance with the present embodiment, the optical element wafer 100 can be burnt in.

In the optical element wafer 100 in accordance with the present embodiment, when the optical element wafer 100 is burnt in, the second electrode 109 of the optical element 200 and the burn-in electrode 160 are used to drive the optical element 200. At this moment, the drive current circulates in the first mirror 102 commonly shared by each of the optical elements 200. Here, let us consider, for example, a case where the substrate 101 is conductive, and the substrate 101 itself is used as a burn-in electrode. In this case, the substrate 101 itself becomes a parasitic resistance. In contrast to this case, in the optical element wafer 100 in accordance with the present embodiment, a drive current does not flow through the substrate 101, such that the substrate 101 itself does not become a parasitic resistance. Accordingly, the optical element wafer 100 can be burnt in more effectively.

According to the optical element wafer 100 in accordance with the present embodiment, the burn-in electrode 160 can be formed on the first mirror 102, and in a configuration that divides the element forming area 210. As a result, the area of the burn-in electrode 160 as viewed in a plan view can be enlarged. Accordingly, a larger current can be circulated.

The more the burn-in electrode 160 divides the element forming area 210, the greater the area in a plan view of the burn-in electrode 160 can be enlarged. In other words, a greater current can be circulated. Also, the more the burn-in electrode 160 divides the element forming area 210, the more the current that circulates in the element forming area 210 can be made uniform. How the element forming area 210 is to be divided may be appropriately decided in view of the number of optical elements 200 to be taken, the burn-in conditions (the amount of current at the time of burn-in, etc.) and the like.

According to the method for manufacturing the optical element wafer 100 in accordance with an embodiment of the present invention, the burn-in electrode 160 and the first electrodes of the optical elements 200 can be formed by the same process. In other words, due to the fact that a process to be exclusively conducted for forming the burn-in electrode 160 is not required, the process for manufacturing the optical element wafer 100 can be simplified.

Although preferred embodiments of the present invention are described above, the present invention is not limited to them, and a variety of modes can be implemented. For example, interchanging the p-type and n-type characteristics of each of the semiconductor layers in the above described embodiments does not deviate from the subject matter of the present invention.

Also, for example, in the embodiments of the present invention described above, the case where the optical element 100 functions as a surface-emitting type semiconductor laser is described. However, the present invention is also applicable to optical elements other than surface-emitting type semiconductor lasers. Optical elements to which the present invention can be applied include, for example, light emitting diodes, photodiodes and the like. When the present invention is applied to a photodiode, the active layer 103 described above can be replaced with a photoabsorption layer. Also, when a burn-in step is conducted, a reverse bias voltage can be applied to an optical element (photodiode) 200.

Also, for example, in the embodiments of the present invention described above, the case where the first electrode 107 is formed on the first mirror 102 is described. However, the first electrode 107 can be formed on the back surface of the substrate 101. In this case also, when the optical element wafer 100 is burnt in, an optical element 200 can be driven by using the second electrode 109 of the optical element 200 and the burn-in electrode 160.

Also, for example, in the embodiments of the present invention described above, materials of AlGaAs system are described. However, materials of other systems, such as, for example, semiconductor materials of AlGaP system, GaInP system, ZnSSe system, InGaAs system, InGaN system, AlGaN system, GaInNAs system, GaAsSb system, etc. can also be used depending on design wavelengths.

1. An optical element wafer comprising:
a substrate;
a plurality of optical elements formed above the substrate; and
a burn-in electrode formed above the substrate, in an area different from an element forming area where the optical elements are formed,
wherein the optical element includes
a first semiconductor layer formed above the substrate,
an active layer formed above the first semiconductor layer,
a second semiconductor layer formed above the active layer,
a first electrode that is electrically connected to the first semiconductor layer, and
a second electrode that is electrically connected to the second semiconductor layer,
wherein each of the optical elements shares the first semiconductor layer, and the burn-in electrode is electrically connected to the first semiconductor layer.

2. An optical element wafer according to claim 1, wherein
the optical element functions as a surface-emitting type semiconductor laser,
the first semiconductor layer is a first mirror, and
the second semiconductor layer is a second mirror.

3. An optical element wafer according to claim 1, wherein
the optical element functions as a light emitting diode,
the first semiconductor layer has a first conductivity type, and
the second semiconductor layer has a second conductivity type.

4. An optical element wafer according to claim 1, wherein the burn-in electrode is formed above the first semiconductor layer, and at an outer circumference of the first semiconductor layer.

5. An optical element wafer according to claim 1, wherein the burn-in electrode is formed above the first semiconductor layer, in a shape that divides the element forming area.

6. An optical element wafer according to claim 1, wherein the burn-in electrode has a width that is 1 mm or greater but 5 mm or smaller.

7. An optical element wafer according to claim 1, wherein material for the burn-in electrode and material for the first electrode is same

8. An optical element wafer comprising:
a substrate;
a plurality of optical elements formed above the substrate; and
a burn-in electrode formed above the substrate, in an area different from an element forming area where the optical elements are formed,
wherein the optical element includes
a first semiconductor layer formed above the substrate,
a light absorbing layer formed above the first semiconductor layer,
a second semiconductor layer formed above the light absorbing layer,
a first electrode that is electrically connected to the first semiconductor layer, and
a second electrode that is electrically connected to the second semiconductor layer,
wherein each of the optical elements shares the first semiconductor layer, and the burn-in electrode is electrically connected to the first semiconductor layer.

9. An optical element wafer according to claim 7, wherein
the optical element functions as a photodiode,
the first semiconductor layer has a first conductivity type, and
the second semiconductor layer has a second conductivity type.

10. An optical element wafer according to claim 7, wherein the burn-in electrode is formed above the first semiconductor layer, and at an outer circumference of the first semiconductor layer.

11. An optical element wafer according to claim 7, wherein the burn-in electrode is formed above the first semiconductor layer, in a shape that divides the element forming area.

12. An optical element wafer according to claim 7, wherein the burn-in electrode has a width that is 1 mm or greater but 5 mm or smaller.

13. An optical element wafer according to claim 7, wherein material for the burn-in electrode and material for the first electrode is same.

14. A method for manufacturing an optical element wafer including a plurality of optical elements having a first semiconductor layer, an active layer or a light absorbing layer and a second semiconductor layer, the method for manufacturing an optical element comprising the steps of:
laminating semiconductor layers for forming at least the first semiconductor layer, the active layer and the second semiconductor layer above a substrate;
patterning the semiconductor layers to form the second semiconductor layer;
patterning the semiconductor layers to form the active layer or the light absorbing layer;
patterning the semiconductor layers to form the first semiconductor layer;
forming a first electrode and a burn-in electrode to be electrically connected to the first semiconductor layer; and
forming a second electrode to be electrically connected to the second semiconductor layer,
wherein the burn-in electrode is formed in an area different from an element forming area where the optical elements are formed.

15. A burn-in apparatus for an optical element wafer, comprising:
a stage on which the optical element wafer according to claim 1 is mounted;
a fixing member for fixing the optical element wafer to the stage;
a probe that is brought in contact with the second electrode of the optical element;
a power supply circuit section that is capable of applying at least one of a current and a voltage to a path extending from the probe, through the optical element and burn-in electrode to the fixing member; and
a position adjusting section that adjusts a position of the probe with respect to the second electrode of the optical element.

16. A burn-in apparatus for an optical element wafer according to claim 15, comprising a temperature adjusting section that adjusts a temperature environment where burn-in of the optical element wafer is conducted.

17. A burn-in method for burning in an optical element wafer recited in claim 1, the burn-in method for burning in an optical element wafer comprising the steps of:
contacting a probe to the second electrode of the optical element; and
applying at least one of a current and a voltage to a path extending from the probe, through the second electrode, the second semiconductor layer, the active layer and the first semiconductor layer, to the burn-in electrode.

18. A burn-in method for burning in an optical element wafer according to claim 17, wherein a plurality of probes are simultaneously brought in contact with the second electrodes of the plurality of optical elements, and at least one of a current and a voltage is applied to each of the optical elements.

19. A burn-in method for burning in an optical element wafer according to claim 17, conducted in a temperature environment at 30° C. or higher.
